(19) United States
(12) Patent Application Publication
(10) Pub. No.: US 2007/0019258 A1
(43) Pub. Date: Jan. 25, 2007

(54) Image forming system

(75) Inventor: Hiroshi Hattori, Fuwa-gun (JP)

Correspondence Address: BANNER & WITCOFF, LTD.;ATTORNEYS FOR CLIENT NOS. 0166889, 006760, 1001 G STREET, N.W., 11TH FLOOR, WASHINGTON, DC, 20001-4597, US

(73) Assignee: Brother Kogyo Kabushiki Kaisha, Nagoya-shi (JP)

(21) Appl. No.: 11/490,310

(22) Filed: Jul. 21, 2006

(30) Foreign Application Priority Data
Jul. 22, 2005 (JP) 2005-212859
Oct. 31, 2005 (JP) 2005-315696

(51) Int. Cl. G03F 3/08

(52) U.S. Cl. 358/518; 358/504

(57) ABSTRACT

An image forming system includes: an image forming device and a data processing device. The image forming device includes: an image forming unit; a color correction information preparing unit preparing color correction information on the basis of an image forming state of the image forming unit; and a color correction information sending unit sending the color correction information. The data processing device includes: a color correction information receiving unit receiving the color correction information; an image data correcting unit correcting image data on the basis of the received color correction information; and an image data sending unit sending the corrected image data to the image forming device, the image forming unit in the image forming device forming an image on the basis of the image data.

### CROSS REFERENCE TO RELATED APPLICATIONS

This application claims priority from Japanese Patent Application Nos. 2005-212859 filed Jul. 22, 2005 and 2005-315696 filed Oct. 31, 2005. The entire content of each of these priority applications is incorporated herein by reference.

### TECHNICAL FIELD

The disclosure relates to an image forming system including a data processing device for sending image data and an image forming device for receiving the image data and forming an image on the basis of the image data, and the data processing device and the image forming device.

### BACKGROUND

Conventionally, an image forming system including an image forming device having an image forming unit for forming an image on the basis of image data sent from the outside and a data processing device having an image data sending unit for sending image data to the image forming device has been proposed. In this kind of image forming system, when the image data sending unit of the data processing device sends the image data to the image forming device, the image forming unit of the data processing device forms an image based on the image data.

The image forming device is configured to perform so-called calibration that prepares a γ table or the like, which is used for color correction processing of correcting color of image data, by forming a predetermined image based on patch data by the image forming unit and reading the image. Furthermore, the image forming device that performs calibration allows the data processing device connected to the image forming device to designate execution timing of calibration as disclosed in U.S. Pat. No. 5,950,036 or transfers the γ table obtained by calibration to a remote information managing device as disclosed in Japanese Unexamined Patent Application Publication No. 2002-214978.

As a method of executing color correction processing depending on the condition of the image forming device, U.S. Pat. No. 6,975,418 B1, for example, discloses configuration in which such color correction processing is executed in the image forming device.

### SUMMARY

In using color correction information such as the γ table obtained by calibration in the image forming system, there are the following two cases: image data sent from the data processing device is corrected based on the color correction information on the side of the image forming device; and image data is corrected on the side of the data processing device and the corrected image data is sent to the image forming device. In the former case, merely by sending image data from the data processing device at all times irrespective of the color correction information, a proper image subjected to the above-mentioned correction can be formed. However, in this case, the image forming device becomes expensive.

On the other hand, when the color correction processing is executed on the side of the data processing device as in the latter case, in the image forming device, it is possible to prevent decrease in the printing processing speed caused by the color correction processing. However, this configuration has a problem that the color correction processing not suited to the image forming device will possibly be executed in the data processing device and an image is formed erroneously on the basis of the image data that has been subjected to the improper color correction processing.

In the latter case, the image forming device can be made inexpensive. However, each time color correction information is prepared in the image forming device, the color correction information has to be input into the data processing device. Especially when a plurality of data processing devices are connected to one image forming device via LAN or the like, the color correction information has to be individually input for each image forming device. Thus, operability of the image forming system deteriorates.

An object of the invention is to provide an image forming system that can form an image favorably reflecting color correction information even when an inexpensive image forming device incapable of correcting image data on the basis of the color correction information is used, that has a good operability and can prevent image formation based on image data that has been subjected to improper color correction processing as well as to provide an image forming device and a data processing device that can form the image forming system.

In order to attain the above and other objects, the invention provides an image forming system including: an

image forming device and a data processing device. The image forming device includes: an image forming unit forming an image on the basis of image data sent from an outside; a color correction information preparing unit preparing color correction information on the basis of an image forming state of the image forming unit; and a color correction information sending unit sending the color correction information in association with the preparation of the color correction information by the color correction information preparing unit. The data processing device includes: a color correction information receiving unit receiving the color correction information sent from the color correction information sending unit; an image data correcting unit correcting image data on the basis of the received color correction information received by the color correction information receiving unit; and an image data sending unit sending the corrected image data to the image forming device, the image forming unit in the image forming device forming an image on the basis of the image data.

According to another aspect, the invention provides an image forming system, including: a data processing device having a correcting unit executing color correction processing; an image forming device having a receiving unit receiving image data that has been subjected to the color correction processing in the data processing device and an image forming unit forming an image on the basis of the image data received by the receiving unit; and a determining unit determining whether or not the color correction processing executed in the data processing device is proper.

According to another aspect, the invention provides an image forming device including: an image forming unit forming an image on the basis of image data sent from the outside; a color correction information preparing unit preparing, on the basis of an image forming state of the image forming unit, color correction information that is used for correcting color of image data: and a color correction information sending unit sending the color correction information in association with the preparation of the color correction information by the color correction information preparing unit.

According to another aspect, the invention provides an image forming device including: an image data receiving unit receiving image data that has been subjected to a color correction processing in a data processing device; an image forming unit forming an image on the basis of the image data received by the image data receiving unit; and a determining unit determining whether or not the color correction processing executed in the data processing device is proper.

According to another aspect, the invention provides a data processing device including: a color correction information receiving unit receiving color correction information; a color correction information storing unit storing the color correction information received by the color correction information receiving unit; an image data correcting unit correcting image data on the basis of the color correction information stored in the color correction information storing unit; and an image data sending unit sending the corrected image data to an image forming device.

### BRIEF DESCRIPTION OF THE DRAWINGS

Illustrative aspects in accordance with the invention will be described in detail with reference to the following figures wherein:

FIG. 1 illustrates an outline of an image forming system according to a first embodiment of the invention;

FIG. 2 is a schematic sectional view showing internal configuration of a printer used in the system of FIG. 1;

FIG. 3 illustrates detailed configuration of a toner removing unit in the printer;

FIG. 4 illustrates measuring patches formed by the printer;

FIG. 5 is a block diagram showing electrical configuration of a control unit in the printer;

FIG. 6 is a control block diagram showing software configuration of the image forming system;

FIG. 7A illustrates an example of a γ table in the control block diagram of FIG. 6;

FIG. 7B illustrates an example of an address book in the control block diagram of FIG. 6;

FIG. 8 is a flowchart showing a calibration execution processing executed by the control unit in the printer;

FIG. 9 is a flowchart showing a processing executed by a personal computer for instructing execution of calibration;

FIG. 10 is a flowchart showing a calibration result reading processing executed by the personal computer;

FIG. 11 is a flowchart showing a printing instruction processing executed by the personal computer;

FIG. 12 is a block diagram showing electrical configuration of an image forming system in accordance with a second embodiment of the invention;

FIG. 13 is a control block diagram showing software configuration of the image forming system in FIG. 12;

FIG. 14 is a flowchart showing a calibration execution processing executed by a printer in the second embodiment;

FIG. 15 is a flowchart showing a calibration data reception processing executed by the personal computer in the second embodiment;

FIG. 16 is a flowchart showing a printing instruction processing executed by the personal computer in the second embodiment;

FIG. 17 is a flowchart showing a printing processing executed by the printer in the second embodiment;

FIG. 18 is a flowchart showing a printing instruction processing executed by the personal computer in accordance with a first modification of the second embodiment;

FIG. 19 is a flowchart showing a calibration number sending processing executed by the printer in accordance with the first modification of the second embodiment;

FIG. 20 is a flowchart showing a printing processing executed by the printer in accordance with the first modification of the second embodiment;

FIG. 21 is a flowchart showing a printing instruction processing executed by the personal computer in a second modification of the second embodiment;

FIG. 22 is a flowchart showing a printing processing executed by the printer in accordance with the second modification of the second embodiment;

FIG. 23 is a flowchart showing a printing instruction processing executed by the personal computer in accordance with a third modification of the second embodiment; and

FIG. 24 is a flowchart showing a printing determination processing executed by the printer in accordance with a third modification of the second embodiment.

### DETAILED DESCRIPTION

An image forming system according to some aspects of the invention will be described while referring to the accompanying drawings wherein like parts and components are designated by the same reference numerals to avoid duplicating description.

Next, embodiments of the invention will be described with reference to figures.

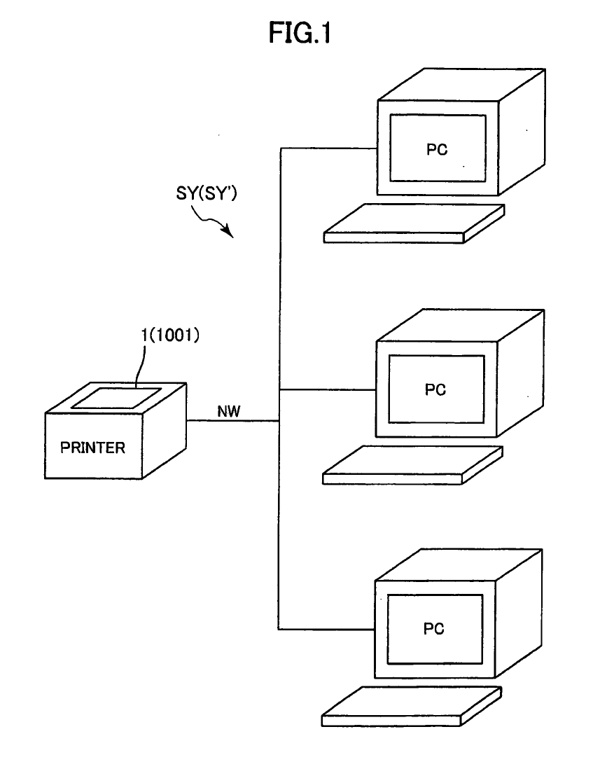

FIG. 1 illustrates an outline of an image forming system SY in accordance with a first embodiment of the invention. As shown in FIG. 1, in the image forming system SY, a plurality of personal computers PC are connected to a color laser printer 1 through a network NW such as LAN and Internet.

First, the configuration of the printer 1 will be described.

[Configuration of Color Laser Printer]

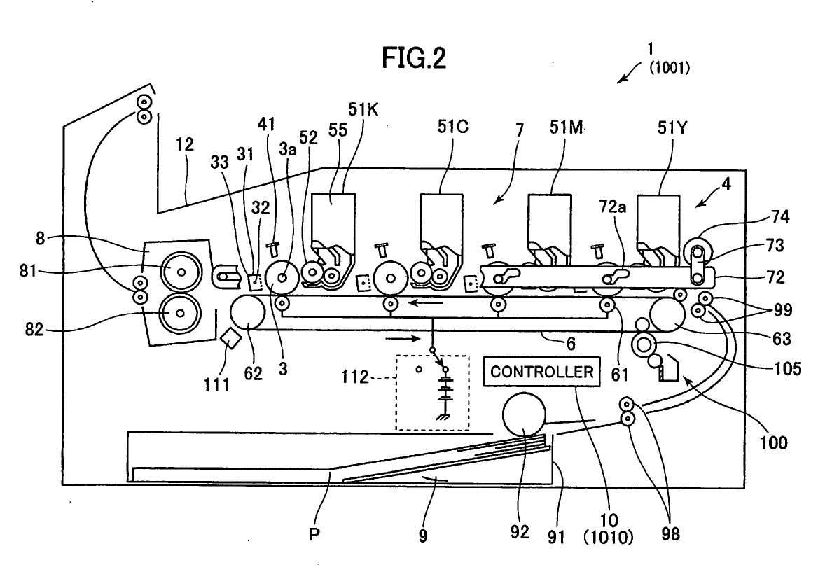

FIG. 2 is a schematic sectional view showing internal configuration of the printer 1. The printer 1 includes a recording engine 7 having a toner image forming unit 4 and a sheet conveying belt 6, a fixing unit 8, a sheet feeding unit 9, stacker 12 and a control unit 10. The printer 1 forms a four-color image according to image data input from the outside on a sheet P.

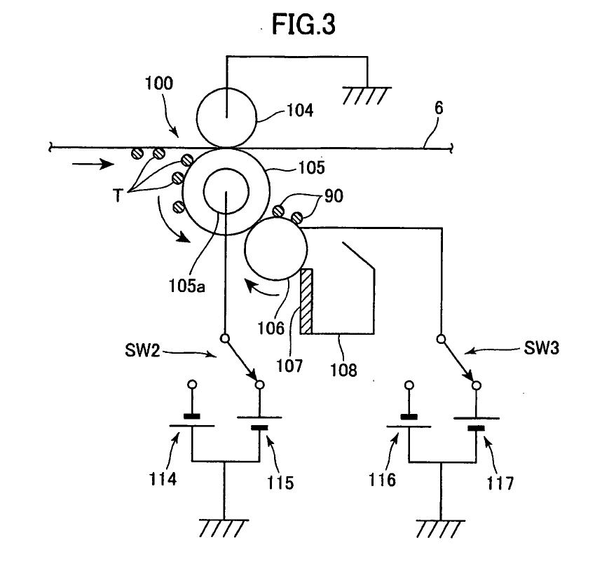

The toner image forming unit 4 includes four developing units 51Y, 51M, 51C and 51K. For each of four toner image forming processes by means of toner T of yellow, magenta, cyan and black stored in these developing units 51Y, 51M, 51C and 51K, respectively (refer to FIG. 3), the toner image forming unit 4a photoconductive drum 3, a charger 31 for uniformly charging the photoconductive drum 3 and an exposing unit 41 for exposing the surface of the charged photoconductive drum 3 with laser beam to form an electrostatic latent image according to image data. A most part of the exposing unit 41 is omitted in the figure and only a part that emits the laser beam is shown.

Hereinafter, configuration of each component will be described in detail. In the following description, when there is need to make a distinction by color, a suffix of Y (yellow), M (magenta), C (cyan) or K (black) is added to a reference numeral of each component and when there is no need to make a distinction by color, the suffix is omitted.

The four photoconductive drums 3 of the toner image forming unit 4, each being formed of a substantially cylindrical member, are arranged at regular intervals in the horizontal direction so as to be rotatable. For example, each photoconductive drum 3 substantially of a cylindrical shape is made from an aluminum base formed with a photoconductive layer with a positively-charging nature. The aluminum base is grounded to a ground line of the printer 1.

Each charger 31 is a so-called scorotron-type charger and formed of a charging wire 32 that extends in the width direction as opposed to the corresponding photoconductive drum 3 and a shield case 33 that stores the charging wire 32 therein and is opened to the side of the corresponding photoconductive drum 3. By applying high voltage to the charging wire 32, the charger 31 charges the surface of the photoconductive drum 3 to positive polarity (for example, +700V). The shield case 33 has a configuration in which a grid is provided at the opened portion on the side of the photoconductive drum 3. By applying a predetermined voltage to the grid, the surface of the photoconductive drum 3 is charged to almost the same potential as the grid voltage.

For each photoconductive drum 3, the exposing unit 41 is disposed downstream of the charger 31 in the rotational direction of the photoconductive drum 3, emits a laser beam corresponding to one color of the image data input from the outside from a light source, scans the laser beam over mirror surfaces of a polygon mirror rotationally driven by a polygon motor and irradiates the laser beam on the surface of the photoconductive drum 3.

When the exposing unit 41 irradiates the laser beam according to the image data on the surface of the photoconductive drum 3, a surface potential of the irradiated portion is lowered to +150 to +200 V, thereby forming an electrostatic latent image on the surface of the photoconductive drum 3.

The developing units 51Y, 51M, 51C and 51K each have configuration in which a developing unit case 55 that stores each color toner T therein is provided with a developing roller 52 and are disposed so that the developing roller 52 may come into contact with the photoconductive drum 3 downstream from the exposing unit 41 in the rotational direction of the photoconductive drum 3. Each developing unit 51 charges the toner T to “+” (positive polarity) and feeds the toner T to the photoconductive drum 3 as a thin layer. Then, in the contact area of the developing roller 52 with the photoconductive drum 3, the developing unit 51 develops a “+” (positive polarity) electrostatic latent image formed on the photoconductive drum 3 by carrying the “+” (positive polarity) charged toner T according to a reversal development method.

The developing roller 52 is shaped like a column using conductive silicone rubber as a base. A coating layer made of resin containing fluorine or rubber material is formed on the surface of the roller 52. The toner T stored in the developing unit case 55 is positively-charged nonmagnetic one-component toner. The developing units 51Y, 51M, 51C and 51K store the toner T of yellow, magenta, cyan and black, respectively, therein.

The sheet feeding unit 9 is disposed at the bottom of this device and is formed of a housing tray 91 for housing sheets P therein and a pickup roller 92 for feeding the sheets P. The sheets P housed in the housing tray 91 are taken out of the sheet feeding unit 9 one by one by using the pickup roller 92 and sent to the sheet conveying belt 6 through conveying rollers 98 and registration rollers 99.

The sheet conveying belt 6 is an endless belt narrower than the width of the photoconductive drum 3 so as to travel together with the sheet P with the sheet P being carried on the upper face thereof. The belt is looped around a driving roller 62 and a follow roller 63. A transfer roller 61 is provided in the vicinity of a location opposed to each photoconductive drum 3 across the sheet conveying belt 6. By rotation of the driving roller 62, the surface of the sheet conveying belt 6 on the side opposed to the photoconductive drum 3 moves from right to left in FIG. 2 as shown by an arrow in FIG. 2. Thus, the sheet P sent from the registration rollers 99 is conveyed sequentially between the belt 6 and the photoconductive drum 3 to the fixing unit 8.

A cleaning roller 105 is disposed at a position near the follow roller 63 on the face of the sheet conveying belt 6 that turns around the driving roller 62. A density detecting sensor 111 is disposed at a position on the driving roller 62 opposed to the sheet conveying belt 6. The density detecting sensor 111 includes a light source for emitting light in the infrared region, a lens for allowing the light from the light source to be irradiated on the sheet conveying belt 6 and a phototransistor for receiving light reflected from the sheet conveying belt 6 and measures the density of a toner image on the sheet conveying belt 6.

FIG. 3 is an explanation view showing detailed configuration of a toner removing unit 100 that is provided with the cleaning roller 105. As shown in FIG. 3, in the cleaning roller 105, a foamed material made of silicone is formed around a shaft member 105a that extends in the width direction of the sheet conveying belt 6. A predetermined bias is applied between the cleaning roller 105 and a metal electrode roller 104 disposed at a position opposed to the cleaning roller 105 across the sheet conveying belt 6. The cleaning roller 105 is disposed so as to rotate while contacting against the sheet conveying belt 6. Due to the bias, the toner T adhered to the sheet conveying belt 6 is removed by the cleaning roller 105. For example, if the electrode roller 104 is connected to the ground line and a bias of the polarity opposite to the polarity of the toner T (for example, −1200 V) is applied to the cleaning roller 105, the toner T can be removed by being attracted by the cleaning roller 105. The cleaning roller 105 is driven by a driving mechanism (not shown) so that the contact areas of the roller 105 may move in the opposite direction with the sheet conveying belt 6.

The cleaning roller 105 is provided with a metal collecting roller 106 (formed of, for example, a Ni-plated iron material or a stainless material) for removing the toner T adhered to the cleaning roller 105 and a storage box (storage container) 108 for storing the toner removed from the cleaning roller 105 therein. The collecting roller 106 is in contact with a rubber cleaning blade 107 and the cleaning blade 107 serves to scrape the toner T adhered to the collecting roller 106 off.

The above-mentioned components including the cleaning roller 105 to the storage box 108 are accommodated in a housing (not shown). The housing is configured so as to be vertically movable by a solenoid (not shown). Thus, when the housing is raised by contracting the solenoid, the cleaning roller 105 comes into contact with the sheet conveying belt 6. On the other hand, when the housing is lowered by extending the solenoid, the cleaning roller 105 separates from the sheet conveying belt 6.

Referring to FIG. 2 again, each transfer roller 61 is configured so as to transfer the toner image formed on the photoconductive drum 3 onto the sheet P conveyed by the sheet conveying belt 6 by being applied with a transfer bias of the polarity (for example, −10 to −15 μA) opposite to the charging polarity of the toner T with respect to the photoconductive drum 3 by a negative voltage current source 112.

The fixing unit 8 has a heating roller 81 and a pressing roller 82 and fixes the toner image on the sheet P by heating and pressing the sheet P on which the toner image is transferred while conveying the sheet P between the heating roller 81 and the pressing roller 82.

The stacker 12 is formed on the upper face of the printer 1. The stacker 12 is provided at the sheet discharging side of the fixing unit 8 and stores the sheet P discharged from the fixing unit 8. The control unit 10 is formed of a control unit using a well-known CPU 10a described later (refer to FIG. 5) and controls the whole operation of the printer 1.

All of the four photoconductive drums 3 are held movable in the upward direction separating from the sheet conveying belt 6 and are positioned by a moving member 72 that is provided to extend over the four photoconductive drums 3. The moving member 72 is formed of a plate-like member having a length long enough to extend over the four photoconductive drums 3 and held so as to be movable in the horizontal direction in FIG. 2. The moving member 72 is provided with four crank-like guiding holes 72a extending in the horizontal direction. A shaft 3a provided at the side face of each photoconductive drum 3 in the longitudinal direction is fitted into each of the guiding holes 72a.

The moving member 72 is provided with a lifting motor 74 through a link 73 for converting a rotational force into a vertical force. According to a command signal from the control unit 10, the lifting motor 74 rotates, thereby moving the moving member 72 in the right or left direction. In this manner, when the moving member 72 moves to the left, the guiding hole 72a also moves to the left and the shaft 3a of each photoconductive drum 3 moves upward along the substantial crank shape of the guiding hole 72a. As a result, the photoconductive drum 3 separates from the sheet conveying belt 6. On the other hand, when the moving member 72 moves to the right, the photoconductive drum 3 is in contact with the sheet conveying belt 6. Normally, an image is formed in the state where the photoconductive drum 3 is in contact with the sheet conveying belt 6.

Operations for forming an image on the sheet P in the printer 1 having the above-mentioned configuration are as follows. First, a sheet P is fed from the sheet feeding unit 9 by the pickup roller 92 and sent to the sheet conveying belt 6 through the conveying rollers 98 and the registration rollers 99. Next, the surface of the rightmost photoconductive drum 3Y in FIG. 2 is uniformly charged by the charger 31 and exposed by the exposing unit 41 according to image data for yellow color input from the outside to form an electrostatic latent image as mentioned above. Next, the yellow toner T positively charged in the developing unit 51Y is fed to the surface of the photoconductive drum 3Y to perform development. Then, the toner image thus formed is transferred on the sheet P conveyed by the sheet conveying belt 6 by the transfer roller 61 to which the transfer bias is applied.

Next, the sheet P is sequentially conveyed at positions opposed to the photoconductive drums 3 for magenta, cyan and black. According to the same procedure as in the yellow toner T, the toner images are formed on the surfaces of the photoconductive drums 3 and superimposed and transferred on the sheet P by the transfer roller 61. The four-color toner image formed on the sheet P is fixed on the sheet P by the fixing unit 8 and then the sheet P is discharged on the stacker 12.

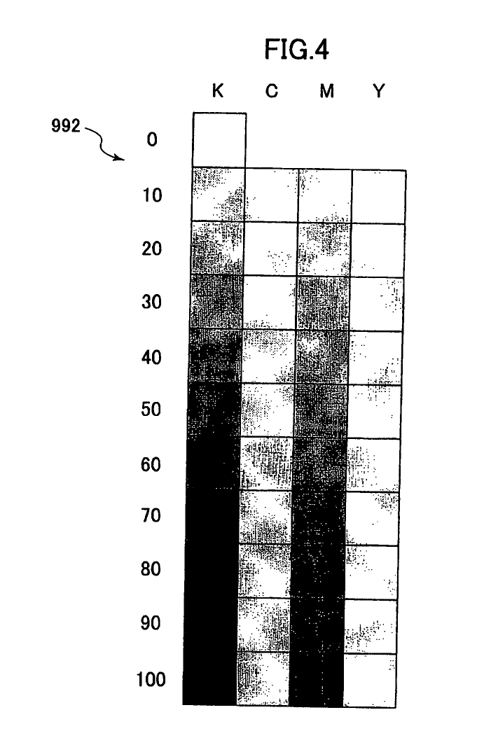

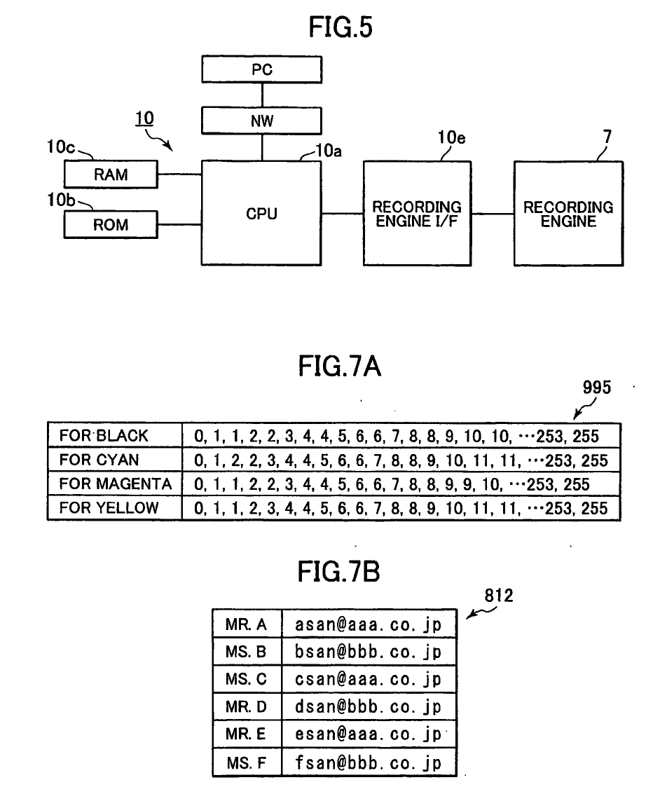

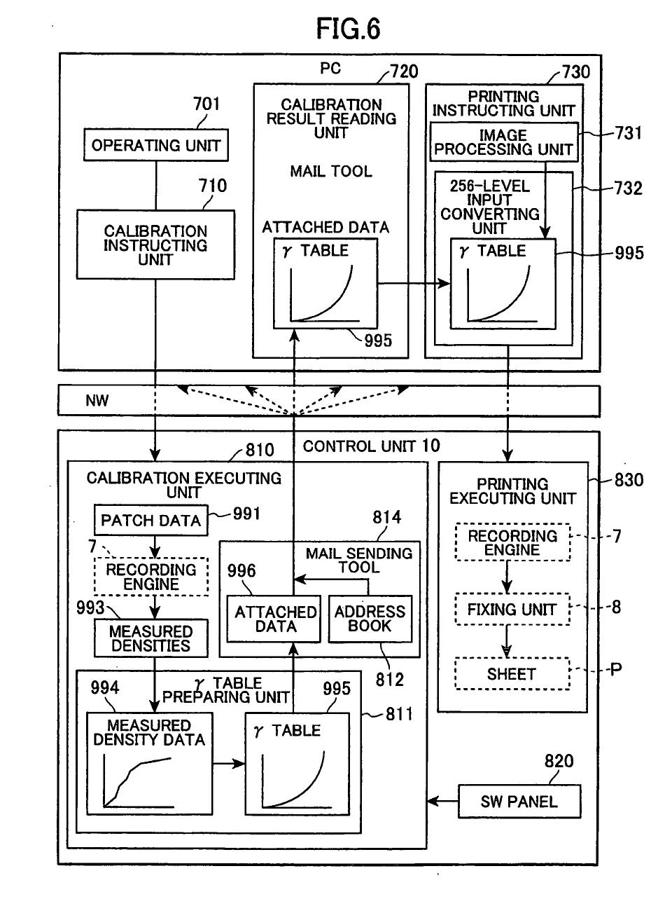

In the printer 1, when calibration is instructed as described later, on the basis of patch data 991 (shown in FIG. 6), measuring patches 992 are formed on the sheet conveying belt 6 by the toner image forming unit 4. As shown in FIG. 4, the measuring patches 992 include eleven black patches formed by black at eleven different densities; ten cyan patches formed by cyan at ten different densities; ten magenta patches formed by magenta at ten different densities; and ten yellow patches formed by yellow at ten different densities. The density of each measuring patch 992 is measured by the density detecting sensor 111. The measuring patches 992 may be measured by the density detecting sensor 111 plural times by rotating the sheet conveying belt 6 plural times, while extending the solenoid (not shown) to stop the operation of the cleaning roller 105 to prevent the cleaning roller 105 from removing toner T from the sheet conveying belt 6. The density detecting sensor 111 outputs signals indicative of the measured densities 993 (shown in FIG. 6).

In this manner, measuring accuracy of the measuring patches 992 can be improved and more satisfactory calibration can be performed. In this case, as the transfer bias is applied to the photoconductive drums 3, no reverse transfer of the toner T occurs. However, to prevent reverse transfer onto the photoconductive drums 3 more satisfactorily, the photoconductive drums 3 may be separated from the sheet conveying belt 6 by sending an instruction signal to the lifting motor 74.

[Configuration of Control System in Image Forming System]

FIG. 5 is a block diagram showing hardware configuration of the control unit 10. As shown in FIG. 5, the control unit 10 is configured as a well-known microcomputer in which a ROM 10b and a RAM 10c are connected to a CPU 10a. The CPU 10a is connected to the recording engine 7 via a recording engine interface (recording engine I/F) 10e and serves to send driving signals to each unit in the recording engine 7 and receives detecting signals from various sensors in the recording engine 7. Furthermore, the CPU 10a is connected to the personal computers PC via the network NW. The personal computers PC each have well-known configuration, in which a display, a mouse, keyboard, etc. are connected to a main unit equipped with a CPU, a ROM, a RAM, a hard disk device and the like.

FIG. 6 is a control block diagram showing software configuration of the image forming system SY.

As shown in FIG. 6, the personal computer PC includes: a calibration instructing unit 710 for instructing execution of calibration to the control unit 10 in the printer 1 according to a screen operation that the user performs by operating an operating unit 701, such as a mouse and a keyboard, while viewing a screen of a display; a calibration result reading unit 720 configured based on a general mail tool; and a printing instructing unit 730 for instructing printing to the control unit 10 in the printer 1.

The control unit 10 in the printer 1 includes: a calibration executing unit 810 for executing calibration and sending the calibration result to the personal computers PC; and a print executing unit 830 for driving the recording engine 7 and printing an image according to image data. The calibration executing unit 810 sends the patch data 991 to the recording engine 7 and receives measured densities 993 of the measuring patches 992 formed on the basis of the patch data 991 from the density detecting sensor 111.

The calibration executing unit 810 has: a γ table preparing unit 811 for preparing γ table data 995 based on measured density data 994 corresponding to the measured densities 993; and a mail sending tool 814 for simultaneously or continually sending, via the network NW, the γ table data 995 as attached data 996 in electronic mails or e-mails to the personal computers PC whose addresses are stored in an address book 812.

Because a method of converting the measured density data 994 into the γ table data 995 is well known, the method is not described in detail. The calibration executing unit 810 also receives an input of a signal from a switch panel (SW panel) 820 provided in the printer 1 to instruct execution of calibration.

FIGS. 7A and 7B show examples of the γ table data 995 and the address book 812, respectively. The γ table data 995 shown in FIG. 7A serves to convert image data, in which density in levels among 256 levels is set for each color, into a numeral value according to the characteristic of the recording engine 7. As shown in FIG. 7A, for example, 256 numerical sequences are set for each color. In the example of FIG. 7A, data is converted so that when the density set for black is “0”, the data is converted into “0” as it is, when “1”, converted into “1” as it is, when “2”, converted into “1” and when “3”, converted into “2”. In this manner, it becomes possible to print a desired image according to the characteristic of the recording engine 7. The mail sending tool 814 sends to the PCs the γ table data 995 that is attached to an e-mail message such as “new calibration data is sent”. Since the γ table data 995 can be expressed as numerical sequences or matrices, the γ table data 995 may be used as a text of a mail. The address book 812, as shown in FIG. 7B, for example, is a well-known address book, in which some personal computers PC (destinations or receivers, to which γ table data 995 should be sent) are registered in association with their addresses.

Referring to FIG. 6 again, the calibration result reading unit 720 in the personal computer PC stores the γ table data 995, which is attached to the e-mail received from the control unit 10 as the attached data 996, in a storage unit, such as the hard disk device, in the personal computer PC in a manner that the γ table data 995 will be available by the printing instructing unit 730. The printing instructing unit 730 includes: an image processing unit 731 for converting image data prepared by various applications into image data in 256 levels (8 bit); and a 256-level input converting unit 732 for further correcting the converted image data by using the stored γ table data 995. The 256-level input converting unit 732 sends the corrected image data to the control unit 10 via the network NW. On the basis of the sent image data, the print executing unit 830 in the control unit 10 drives the recording engine 7 and the fixing unit 8 and prints an image corresponding to the image data on a sheet of paper P.

It is noted that the calibration result reading unit 720 in the personal computes PC may store the mail having the attached γ table data 995 in a manner the same as for other general mails. Alternatively, the calibration result reading unit 720 may store the γ table data 995 so as to be available by the printing instructing unit 730 and then automatically delete the mail.

[Control, Operations and Effects Achieved by Control System]

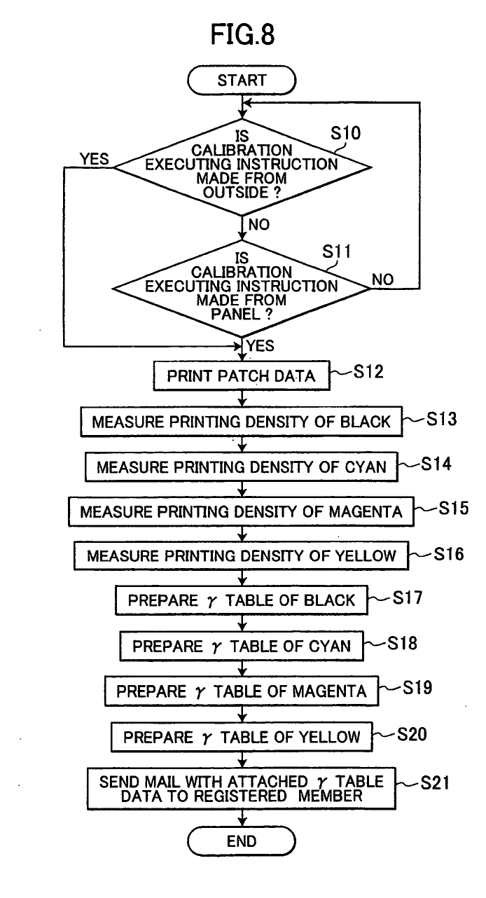

Next, processings in the personal computers PC and the control unit 10 will be described with reference to FIG. 8-FIG. 11.

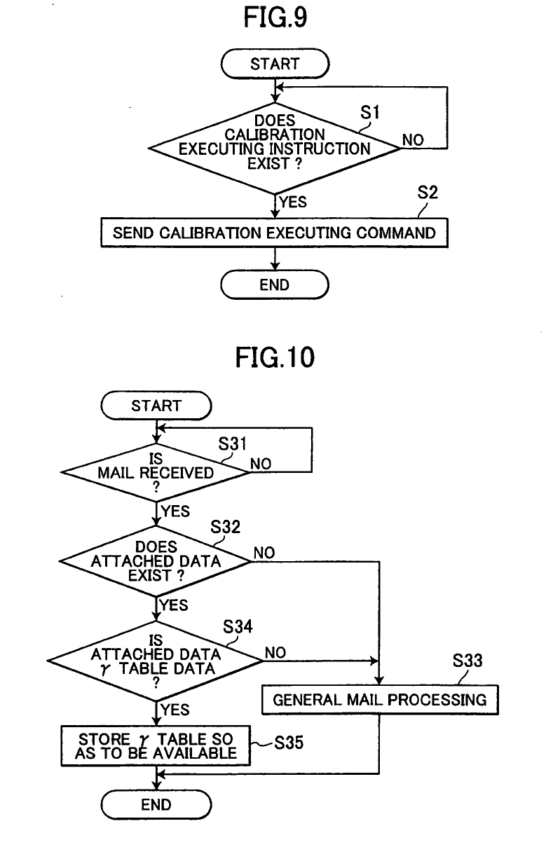

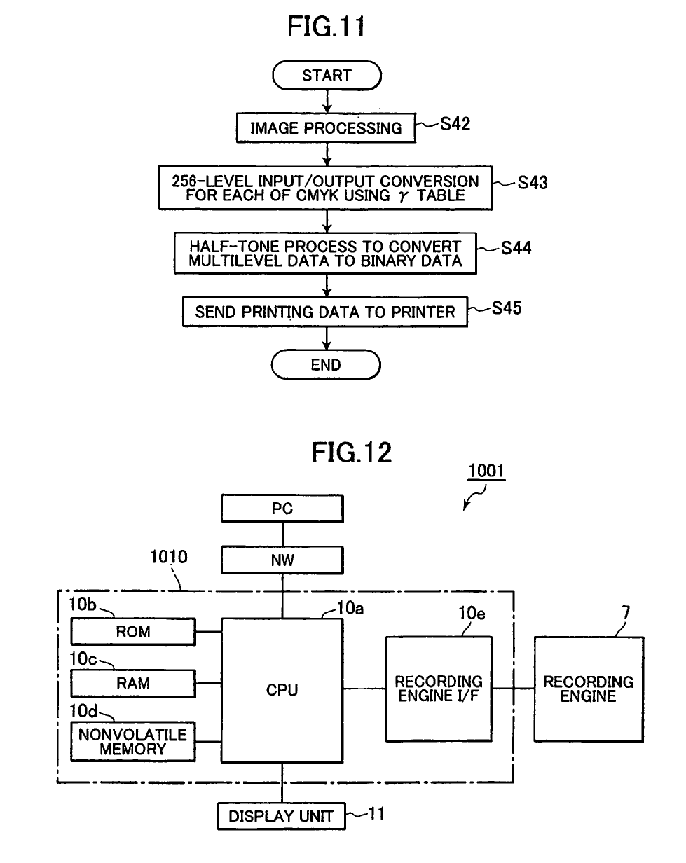

It is noted that a program of FIG. 8 is stored in the ROM 10b of the printer 1. By executing the program of FIG. 8, the CPU 10a of the printer 1 serves as the calibration executing unit 810. Programs of FIGS. 9-10 are stored in the hard disk device of the personal computer PC. By executing the program of FIG. 9, the CPU of the personal computer PC serves as the calibration instructing unit 710. By executing the program of FIG. 10, the CPU of the personal computer PC serves as the calibration result reading unit 720. By executing the program of FIG. 11, the CPU of the personal computer PC serves as the printing instructing unit 730.

FIG. 8 is a flowchart showing calibration execution processing executed by the control unit 10 in the printer 1. This processing is started when power of the printer 1 is turned on.

When the processing is started, first, in S10, it is determined whether or not an instruction for executing calibration is made from the outside. In the absence of the above-mentioned external instruction (S10: No), in S11, it is determined whether or not an instruction for executing calibration is made from the switch panel 820. In the absence of the instruction from the switch panel 820 (S11: No), the processing proceeds to S11 again. In this manner, through the loop processing in S10 and S1, the processing is waited until the instruction for executing calibration is made from the outside or the switch panel 820. When the instruction for executing calibration is made from the outside or the switch panel 820 (S10: Yes or S1: Yes), the processing proceeds to S12.

In S12, the measuring patches 992 are printed by driving the recording engine 7 on the basis of the patch data 991. In S13, S14, S15, and S16, based on the signals sent from the density detecting sensor 111, print densities of the black, cyan, magenta, and yellow measuring patches 992 are measured in this order.

In S17, S18, S19 and S20, based on the measured print densities, the γ table data 995 for black, cyan, magenta, and yellow is prepared, in this order. In this manner, the γ table data 995 for each color is prepared. In S21, a mail having the γ table data 995 for all the colors as the attached data 996 is sent to each member that is registered in the address book 812, that is, personal computers PC whose addresses are registered in the address book 812, and the processing is finished.

FIG. 9 to FIG. 11 show processings executed by the personal computer PC. FIG. 9 shows a processing in the calibration instructing unit 710. When this processing is started, first, in S1, it is determined whether or not an instruction for execution of calibration is inputted by manipulating the operating unit 701 while viewing the screen. In the absence of the instruction for execution of calibration (S1: No), the processing is waited in S1. In the existence of the instruction for execution of calibration (S1: Yes), in S2, a calibration executing command is sent from the PC to the control unit 10 in the printer 1. When the calibration executing command is received by the control unit 10, determination is made that the instruction for executing calibration is made from the outside in S10 (FIG. 8) and calibration is executed.

FIG. 10 is a flowchart showing a processing in the calibration result reading unit 720. In this processing, first, in S31, the processing is waited until an e-mail is received (S31: No). Then, when the e-mail is received (S31: Yes), in S32, it is determined whether or not the e-mail has attached data. In the absence of the attached data (S32: No), in S33, the mail is processed as in general mail tools and the processing is finished and restarted from S31.

On the other hand, when the mail received in S31 has the attached data (S32: Yes), in S34, it is determined whether or not the attached data is γ table data 995. When the attached data is not γ table data 995 (S34: No), the mail is processed as in general mail tools in S33 and the processing is finished and restarted from S31.

When the attached data is γ table data 995 (S34: Yes), the γ table data 995 is stored in a predetermined storage area of the RAM of the PC in S35 so as to be available by the 256-level input converting unit 732 and the processing is finished and restarted.

FIG. 11 is a flowchart showing a processing in the printing instructing unit 730. When the processing is started, first, in S42, image processing is executed to convert image data, which has been prepared by another application, into image data indicative densities of levels among 256 levels (8 bit). In S43, the converted image data is further corrected by using the γ table data 995 that has been stored in S35. That is, image data, in which densities of levels among 256 levels are set for each color of C (cyan), M (magenta), Y (yellow) and K (black), is converted using the γ table data 995 for the subject color. In S44, the converted image data (multilevel data in 256 levels) is further converted into binary data (dot data and non-dot data) through a well-known half-tone process. The binary data is sent to the printer 1 in S45 and the processing is finished. When the printer 1 receives the image data, the printer 1 performs printing based on the received image data.

In this manner, in the image forming system SY in accordance with the first embodiment, each time calibration is executed (S12 to S20), the newly obtained γ table data 995 is automatically sent to the registered PCs according to the address book 812 (S21), and in each registered personal computer PC that receives the γ table data 995, the γ table data 995 is stored so as to be usable by the 256-level input converting unit 732 (S35). It is noted that the γ table data 995 thus stored will be updated (S35) each time the new γ table data 995 is received (S34: Yes). Accordingly, even when the user does nothing or the printer 1 has no correcting function using the γ table data 995, an excellent image according to change in the characteristic of the recording engine 7 can be printed at all times. Therefore, the operability can be improved extremely satisfactorily and the image forming system can be easily configured.

Especially when a plurality of personal computers are connected to one printer 1 via LAN or the like, it becomes possible to simultaneously or continually send the γ table data to those registered personal computers, thereby further improving operability.

With the configuration in this embodiment, since color correction processing is executed on the side of the personal computer PC, load applied to the printer 1 can be reduced.

The γ table data 995 may be sent from the printer 1 to the registered personal computers PC through various types of communication methods other than the e-mails.

### Second Embodiment

Next, an image forming system SY′ according to a second embodiment of the invention will be described with reference to FIG. 1 to FIG. 4 and FIG. 12 to FIG. 17. The image forming system SY′ according to the second embodiment is the same as the image forming system SY according to the first embodiment except for the points described below.

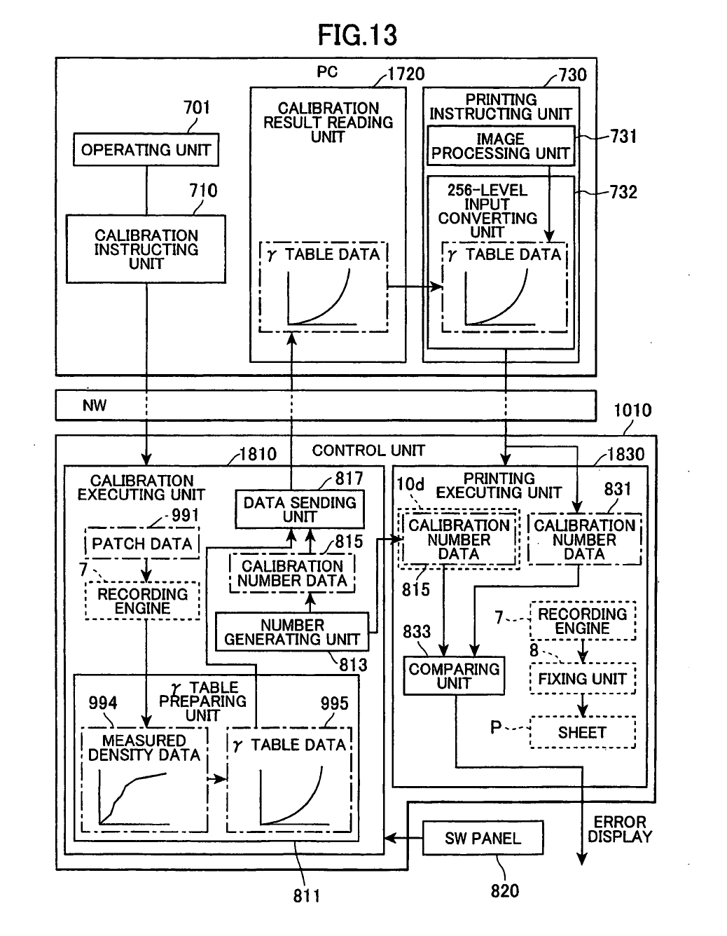

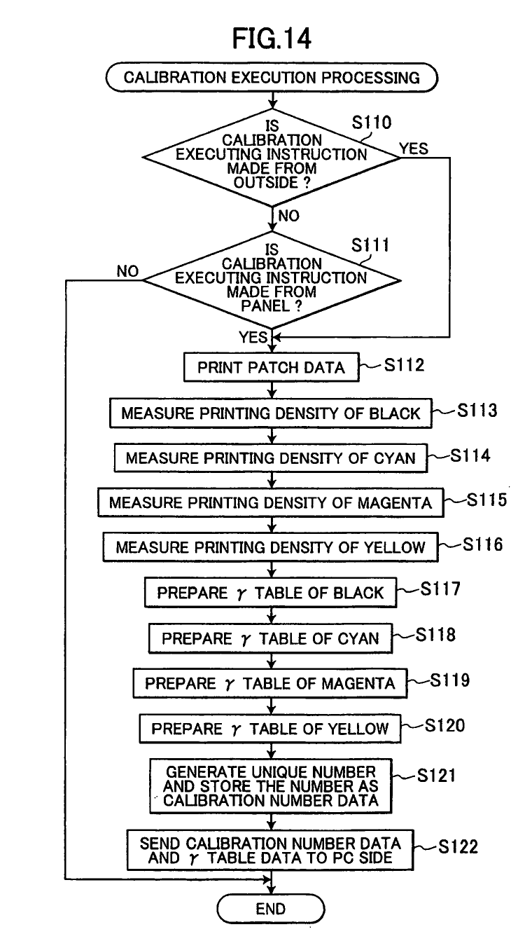

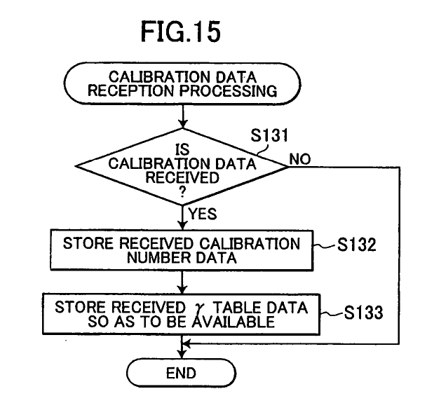

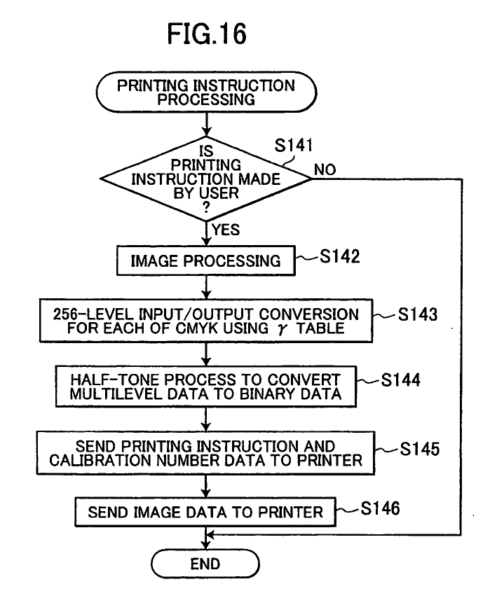

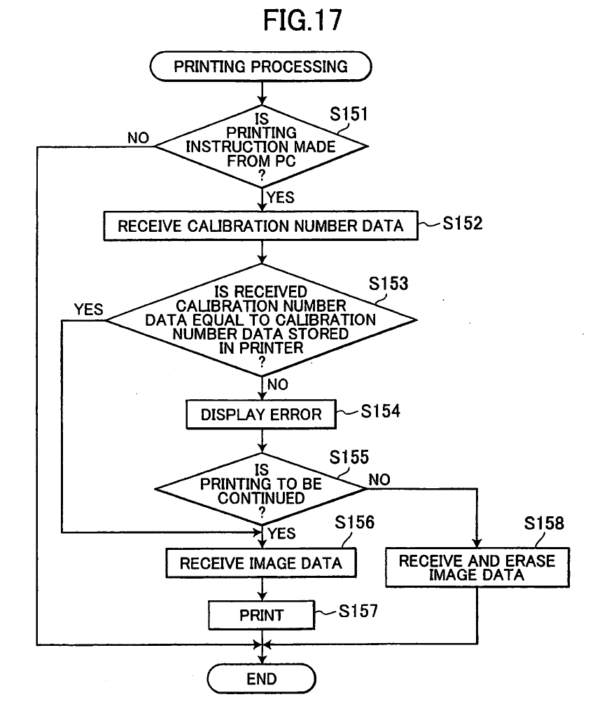

The image forming system SY′ according to the second embodiment has a plurality of personal computers PC and a color laser printer 1001 which is connected to the plurality of personal computers PC through a network NW such as LAN and Internet. The color laser printer 1001 has the same configuration as the color laser printer 1 of the first embodiment except that the color laser printer 1001 has the control unit 1010 in place of the control unit 10 of the first embodiment. The control unit 1010 has the hardware configuration as shown in FIG. 12 and the software configuration as shown in FIG. 13 to execute the processings of FIG. 14 and FIG. 17. The personal computers PC according to the present embodiment are the same as those in the first embodiment except that each personal computer PC has the software configuration shown in FIG. 13 to execute the processings of FIG. 15 and FIG. 16.

As shown in FIG. 12, the control unit 1010 is the same as the control unit 10 of the first embodiment (FIG. 5) except that a nonvolatile memory 10d and a display unit 11 are further connected to the CPU 10a. The display unit 11 is configured from an LCD panel, for example, and is capable of displaying images.

As shown in FIG. 13, the personal computer PC according to the second embodiment has the same software configuration as that in the first embodiment (FIG. 6) except that the personal computer PC has a calibration result reading unit 1720 in place of the calibration result reading unit 720. The calibration result reading unit 1720 is the same as the calibration result reading unit 720 except that the calibration result reading unit 1720 is not configured based on a general mail tool.

The control unit 1010 in the printer 1001 includes a calibration executing unit 1810 and a print executing unit 1830 in place of the calibration executing unit 810 and the print executing unit 830 in the first embodiment.

The calibration executing unit 1810 is the same as the calibration executing unit 1810 except that the calibration executing unit 1810 includes: a number generating unit 813 for generating a unique number (calibration number) corresponding to one set of γ table data 995 that the γ table preparing unit 811 has prepared and for storing the calibration number in the nonvolatile memory 10d; and a data sending unit 817 for associating the γ table data 995 with calibration number data 815 indicative of the unique number that the number generating unit 813 has generated, and for sending the associated pair of γ table data 995 and calibration number data 815 as calibration data to the personal computers PCs. It is noted that the data sending unit 817 sends the calibration data to the personal computers PCs through the network NW via a general type of communication method.

The print executing unit 1830 is the same as the print executing unit 830 in the first embodiment except that the print executing unit 1830 has a comparing unit 833 for comparing the calibration number data 815 that is stored in the nonvolatile memory 10d with calibration number data 831 that will be received from the PCs as will be described later in greater detail.

(Flow of Processing)

Next, processings in the personal computers PC and the control unit 1010 will be described with reference to FIG. 14-FIG. 17.

It is noted that programs of FIG. 14 and FIG. 17 are stored in the ROM 10b of the printer 1. By executing the program of FIG. 14, the CPU 10a of the printer 1 serves as the calibration executing unit 1810. By executing the program of FIG. 17, the CPU 10a of the printer 1 serves as the print executing unit 1830. Programs of FIGS. 15 and 16 are stored in the hard disk device of the personal computer PC. By executing the program of FIG. 15, the CPU of the personal computer PC serves as the calibration result reading unit 1720. By executing the program of FIG. 16, the CPU of the personal computer PC serves as the printing instructing unit 730.

FIG. 14 is a flowchart showing calibration execution processing executed by the control unit 1010. This processing is repeatedly executed regularly at relatively short time intervals after the power of the printer 1001 is turned on. It is noted that in the processes of FIG. 14, processes in S110 to S120 are the same as the processes in S10 to S20 (FIG. 8) in the first embodiment. More specifically, in S110 to S120, the γ table data 995 is prepared for each color in the same manner as in the first embodiment. It is noted that the thus prepared γ table data 995 is also stored in the nonvolatile memory 10d.

Next, in S121, a unique number is generated and the calibration number data 815 (FIG. 13) that identifies the unique number is stored in the nonvolatile memory 10d. Here, the unique number is made from a combination of printer identification information unique to the printer 1001 and information on the number of times calibration has been performed in the same printer 1001. For example, if a printer identification number is “PRI100” and a calibration number is “0020” indicating that the presently-executed calibration operation is the twentieth calibration executed in the printer 1001, the unique number is made as “PRI1000020”. Thus, the unique number is information unique to each source that generates the γ table data 995. Thus, in the circumstance where a plurality of printers 1001 are connected to each PC via the network, according to the unique number, the PC can identify the source of the γ table data 995. Moreover, since the unique number is unique to each γ table data 995 prepared in each printer 1001, it is ensured that the same unique numbers will not be generated by different printers 1001 and that the same unique numbers will not be generated in the same printer 1001.

It is noted that in S121, the CPU 10a counts the number of times calibration has been performed, and combines the number of counts with the printer identification number.

Next, in S122, the calibration number data 815 is associated with the γ table data 995 that has been prepared in S117-S120, and the associated pair calibration number data 815 and the γ table data 995 is sent as a set of calibration data to the personal computers PC through the network NW via the general type of communication method.

It is noted that the personal computers PC, to which the calibration data is automatically sent from the printer 1001, may be all of the personal computers PC that are connected to the printer 1001 via LAN or the like or may be only some personal computer PC that is previously registered in the printer 1001 similarly as in the first embodiment.

FIG. 15 and FIG. 16 show processings executed by the personal computer PC.

FIG. 15 is a flowchart showing a calibration data reception processing.

The calibration data reception processing in FIG. 15 is repeatedly executed at regular intervals. When the processing is started, first, in S131, it is determined whether or not a set of calibration data (that is, a pair of the γ table data 995 and the calibration number data 815) is received. In the absence of reception (No in S131), the processing is finished. On the other hand, in the existence of reception (Yes in S131), the calibration number data 815 is stored in S132. Subsequently, in S133, the γ table data is stored in the storage unit, such as the hard disk device, in the personal computer PC, in association with the calibration number data so as to be available.

FIG. 16 is a flowchart showing a printing instruction processing.

The printing instruction processing is repeatedly executed regularly at relatively short time intervals. When the processing is started, first, in S141, it is determined whether or not a printing instruction is issued from a user. In the absence of the printing instruction (No in S141), the processing is finished. In the existence of the printing instruction (Yes in S141), the processes of S142-S144 are executed. The processes of S142-S144 are the same as those of S42-S44 in the first embodiment (FIG. 11). It is noted that in S143, color correction is executed by using the γ table data that has been stored in S133 of FIG. 15 at the latest. Next, in S145, prior to sending of the image data, a printing instruction is sent to the printer 1001, and calibration number data (which will now be referred to as calibration number data 831) that corresponds to the γ table data that is used in the color correction processing in S143 is sent to the printer 1001. Then, in S146, image data that is prepared in S142-S144 is sent to the printer 1001 and the processing is finished.

In the image forming system SY′ in accordance with the second embodiment, each time the calibration execution processing shown in FIG. 14 is executed, a newly-obtained set of γ table data 995 is automatically sent to the personal computer PC in S122 (FIG. 14). In the personal computer PC, the γ table data 995 is stored so as to be available by the 256-level input converting unit 732 in S133 (FIG. 15). Thus, the stored γ table data 995 is updated in S133 each time new γ table data 995 is received.

In the above description, the calibration data is automatically sent in S122 from the printer 1001 to the personal computer PC. However, the processing in S122 may be omitted from the calibration execution processing of FIG. 14. Instead, the calibration data may be sent to a personal computer PC on the request from the subject personal computer PC. When the calibration data is sent from the printer 1001 to the personal computer PC, the γ table data 995 in the calibration data is associated with the calibration number data 815 in the calibration data 815, and is stored so as to be available by the personal computer PC.

Next, printing processing executed by the printer 1001 will be described.

As shown in FIG. 13, the printer 1001 receives, from the personal computer PC, image data that has been subjected to the color correction processing of S143 (FIG. 16) in the personal computer PC according to the γ table data and calibration number data 831 that indicates the calibration number identifying the γ table data that has been used in the color correction processing. On the basis of the image data, the print executing unit 830 drives the recording engine 7 and the fixing unit 8 to print an image corresponding to the image data on a sheet of paper P.

The comparing unit 833 compares calibration number data 815 that is being presently stored in the nonvolatile memory 10d and therefore that has been obtained through the latest-executed calibration processing of FIG. 14 with the received calibration number data 831 to determine whether or not the color correction processing of S143 that has been executed in the personal computer PC side is proper. When the received calibration number data 831 is the same as the latest calibration number data 815 in the nonvolatile memory 10d, it is known that the color correction processing of S143 has been executed by using the γ table data that has been obtained by the latest-executed calibration execution processing of FIG. 14, and therefore the comparing unit 833 determines that the color correction processing of S143 is proper. On the other hand, when the received calibration number data 831 is different from the latest calibration number data 815 in the nonvolatile memory 10d, it is known that the color correction processing of S143 has been executed by using the γ table data that has been obtained by another calibration execution processing of FIG. 14 that had been executed prior to the latest-executed calibration execution processing, and therefore the comparing unit 833 determines that the color correction processing of S143 is improper.

When it is determined that the color correction processing of S143 executed in the personal computer PC is improper, an error is displayed and a printing process based on the image data is disabled.

Next, the printing processing will be described in greater detail with reference to FIG. 17. FIG. 17 is a flowchart showing the printing processing. The printing processing is repeatedly executed regularly at relatively short time intervals.

When the printing processing is started, first, in S151, it is determined whether or not a printing instruction is made from some personal computer PC. In the absence of the printing instruction (No in S151), the processing is finished. In the existence of the printing instruction (Yes in S151), the calibration number data 831 sent from the personal computer PC is received in S152. Subsequently, in S153, it is determined whether or not the received calibration number data 831 is equal to the latest calibration number data 815 that is presently being stored in the nonvolatile memory 10d.

When the received calibration number data 831 is equal to the latest calibration number data 815 (Yes in S153), and the process proceeds to S156.

On the other hand, when the received calibration number data 831 is different from the latest calibration number data 815 (No in S153), an error is displayed on the display unit 11 (FIG. 12) in S154. In the error display, for example, a comment such as “calibration data is improper” is displayed on the display unit 11 to directly or indirectly inform the user that the color correction processing of S143 that has been executed on the personal computer side is improper. Thus, the error is informed the user when it is determined that the color correction processing of S143 is improper. The user can easily recognize the occurrence of improper situation and promptly deal with the situation.

In the above description, the display unit 11 informs the user of the error. However, the error may be informed the user by the use of a buzzer or the like, or by outputting error information to the personal computer PC.

After performing the error display in S154, information for inquiring whether or not printing should be continued is displayed on the display unit 11. For example, a comment “Printing is performed?” to prompt the user to select is displayed on the display unit 11. When information is not inputted within a predetermined period of time after the display, or when an instruction to stop printing is inputted from the user (No in S155), image data is received and erased in S158. On the other hand, when an instruction to continue printing is inputted from the user (Yes in S155), the procedure proceeds to S156. In S156, the image data is received. Then, printing is performed in S157.

With this configuration, printing is temporarily prohibited by displaying in S155 the information of inquiring whether or not printing should be continued on the display unit 11 after performing an error display in S154. However, the processes of S156 and S157 release the prohibition of printing and performs printing by driving the recording engine 7 by using the image data that has been subjected to the improper color correction processing. This configuration is convenient for the user who intends to promptly form an image even in the improper condition.

As described above, according to the image forming system SY′ in accordance with the second embodiment, when it is determined that the color correction processing in the personal computer PC is improper, the CPU 10a in the printer 1001 disables image formation. Thus, image formation according to the image data subjected to the improper color correction processing can be effectively prevented.

Since the printer 1001 generates the γ table data 995 and sends the γ table data 995 to the personal computer PC, the color correction processing can be suitably executed on the side of the personal computer PC.

The printer 1001 determines whether or not the color correction processing has been executed on the basis of the latest γ table data 995. Thus, when the printer 1001 determines that image data has been subjected to color correction processing based on γ table data that is different from the latest γ table data 995 and therefore that the image data is improper, the printer 1001 disables printing based on the improper image data.

Furthermore, the CPU 10a can easily and accurately determine whether or not the color correction processing is proper by determining whether or not the calibration number data 831 received from the personal computer PC is equal to the latest calibration number data 815 stored in the nonvolatile memory 10d.

The γ table data 995 corresponds to the unique calibration number data 815. Thus, even in the situation where a plurality of printers 1001 are connected via the network, it is possible to identify the source of the γ table data 995. The same calibration number 815 is not assigned to different printers 1001. Accordingly, the printer 1001 can perform accurate determination on whether the color correction processing executed on the PC side is proper for the subject printer 1001.

Furthermore, the printer 1001 can accurately determine whether or not the color correction processing executed in the personal computer PC is based on the latest γ table data by simply comparing the calibration number data 831 with the calibration number data 815 that is stored in the nonvolatile memory 10d.

Since the density detecting sensor 111 measures the density of the measuring patches 992 and on the basis of the resultant measured density data 994, prepares the γ table data 995, the color correction processing can be suitably executed with high accuracy.

Furthermore, when it is determined that color correction has been performed on the PC side based on the improper γ table data, the display unit 11 can inform the user of the improper condition, thereby allowing the user to perform a rapid response.

In the present embodiment, the data sending unit 817 may send the calibration data in S122 to the PCs in the form of data attached to e-mail in the same manner as in the first embodiment. In this case, the calibration result reading unit 1720 may be configured based on a general mail tool in the same manner as the calibration result reading unit 720 in the first embodiment.

### FIRST MODIFICATION OF THE SECOND EMBODIMENT

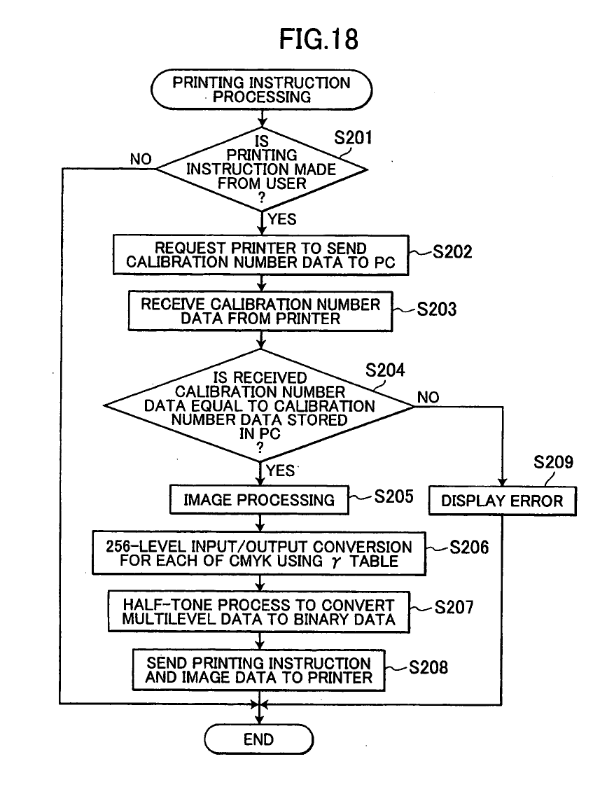

A first modification of the second embodiment of the invention will be described with reference to FIG. 18 to FIG. 20.

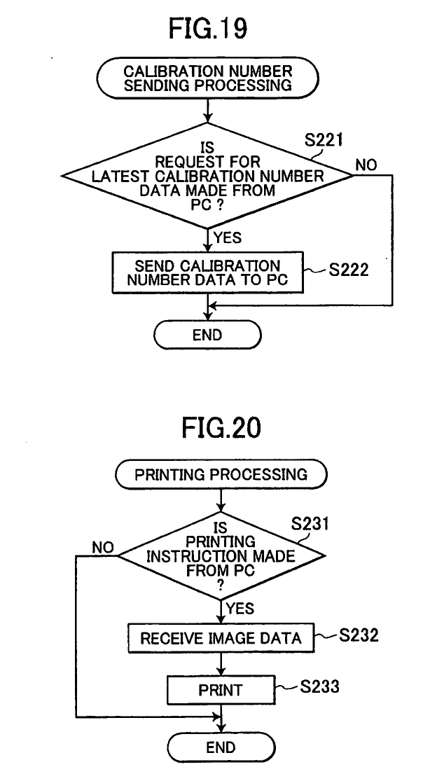

According to the present modification, the personal computer PC executes a printing instruction processing of FIG. 18 in place of the printing instruction processing of FIG. 16, and the printer 1001 executes a printing processing of FIG. 20 in place of the printing processing of FIG. 17 in the second embodiment. The printer 1001 also executes a calibration number sending processing in FIG. 19. It is noted that the printer 1001 executes the calibration executing processing of FIG. 14 in the same manner as in the second embodiment. The personal computer PC executes the calibration data receiving processing of FIG. 15 in the same manner as in the second embodiment.

In other words, according to this modification, the software configuration is modified from FIG. 13 in that the comparing unit 833 is provided on the side of the personal computer PC, not the control unit 1010 of the printer 1001, and in that the personal computer PC does not send calibration number data 831 to the printer 1001.

More specifically, prior to execution of the color correction processing of S206 (FIG. 18), the personal computer PC determines whether or not the color correction processing to be executed is proper. When the personal computer PC determines that the color correction processing to be executed is improper, the personal computer PC disables the color correction processing of S206.

As shown in FIG. 18, according to the printing instruction processing of this modification, first, in S201, the personal computer PC determines whether or not a printing instruction is issued from a user. In the absence of the printing instruction (No in S201), the processing is finished. In the existence of the printing instruction (Yes in S201), in S202, the personal computer PC requests the printer 1001 to send the calibration number data 815 that is being presently stored in the nonvolatile memory 10d and therefore that is the latest calibration number data 815 that has been obtained through the latest-executed calibration processing of FIG. 14. In response to the request from the personal computer PC, the printer 1001 sends the calibration number data 815 to the personal computer PC by executing the calibration number sending processing shown in FIG. 19.

The calibration number sending processing is repeatedly performed by the printer 1001 regularly at relatively short time intervals. When the processing is started, it is determined in S221 whether or not the personal computer PC issues a request to send the calibration number data to the personal computer PC. When the process of S202 in FIG. 18 is executed and the sending request is issued (Yes in S221), the latest calibration number data 815 that is presently being stored in the nonvolatile memory 10d is sent to the personal computer PC in S222. On the other hand, the sending request is not issued (No in S221), the processing is finished.

When the printer 1001 sends the calibration number data 815 to the personal computer PC in S222 of FIG. 19, the personal computer PC receives the calibration number data in S203 of FIG. 18.

Then, in S204, the personal computer PC determines whether or not the received calibration number data 815 is equal to the calibration number data that is presently being stored in the personal computer PC.

When the received latest calibration number data 815 is different from the calibration number data stored in the personal computer PC (No in S204), an error is displayed on a screen of the personal computer PC in S209 in the same manner as in S154 (FIG. 17) of the second embodiment.

On the other hand, when the received latest calibration number data 815 is equal to the calibration number data stored in the personal computer PC (Yes in S204), processes of S205-S207 are executed. The processes of S205-S207 are the same as those of S42-S44 in the first embodiment (FIG. 11). It is noted that in S206, color correction is executed by using the γ table data 995 that has been stored in S133 of FIG. 13 at the latest and that corresponds to the calibration number data that is now stored in the personal computer PC.

Then, in S208, a printing instruction and the corrected image data are sent to the printer 1001, and then the processing is finished.

In the printer 1001, the corrected image data is acquired and the printing processing is executed as shown in FIG. 20.

This printing processing is repeatedly performed regularly at relatively short time intervals. When a printing instruction is made from the personal computer PC (Yes in S231), the image data is received in S232 and printing is performed based on the image data in S233.

On the other hand, when any printing instruction is not made from the personal computer PC (No in S231), the processing is finished.

As described above, in accordance with the first modification of the second embodiment, the personal computer PC has a function corresponding to the comparing unit 833. That is, prior to executing the color correction processing, the personal computer PC determines whether or not the improper color correction processing will be performed. It is therefore possible to easily stop executing the improper color correction processing.

### SECOND MODIFICATION OF THE SECOND EMBODIMENT

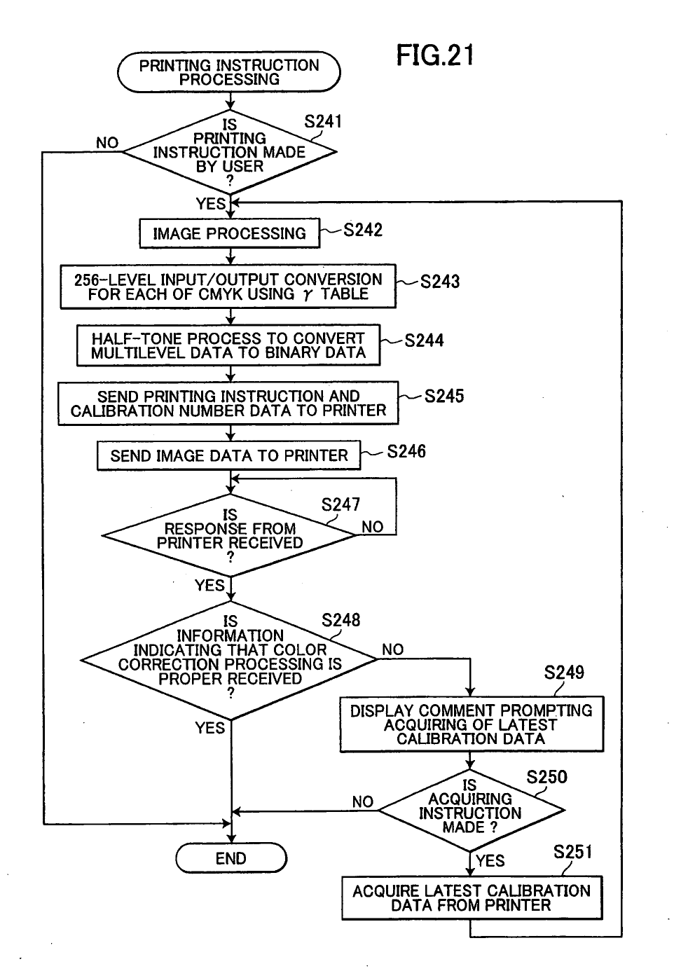

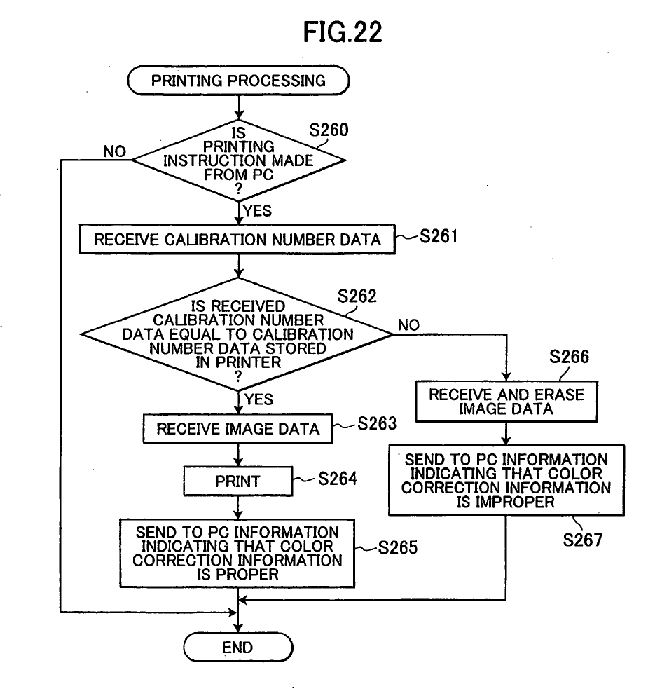

Next, a second modification of the second embodiment of the invention will be described with reference to FIG. 21 and FIG. 22.

According to the present modification, the personal computer PC executes a printing instruction processing of FIG. 21 in place of the printing instruction processing of FIG. 16, and the printer 1001 executes a printing processing of FIG. 22 in place of the printing processing of FIG. 17 in the second embodiment. It is noted that the printer 1001 executes the calibration executing processing of FIG. 14 in the same manner as in the second embodiment. The personal computer PC executes the calibration data receiving processing of FIG. 15 in the same manner as in the second embodiment.

According to this modification, when the printer 1001 determines that the color correction processing that has been executed on the PC side is improper, the printer 1001 sends to the personal computer PC data required for executing the proper color correction processing. That is, when the printer 1001 determines that the color correction processing that has been executed on the PC side is improper, the printer 1001 sends to the personal computer PC the latest γ table data 995 that is obtained at the latest-executed calibration processing of FIG. 14.

The printing instructing process of FIG. 21 is repeatedly executed regularly at relatively short time intervals. In the printing instructing process of FIG. 21, processes S241-S246 are executed in the same manner as in S141-S146 (FIG. 16) in the second embodiment.

After image data is sent in S246, in S247, the personal computer PC waits for a response sent from the printer 1001.

FIG. 22 shows printing processing executed by the printer 1001 in this modification.

The printing process of FIG. 22 is repeatedly executed regularly at relatively short time intervals. In the printing process of FIG. 22, processes S260-S262 are executed in the same manner as in S151-S153 (FIG. 17) in the second embodiment.

When the received calibration number data 831 is equal to the latest calibration number data 815 stored in the nonvolatile memory 10d (Yes in S262), in S263 the printer 1001 receives image data from the personal computer PC, and performs printing based on the received image data in S264. After printing, in S265, the printer 1001 sends to the personal computer PC information informing that the γ table data that has been used in the PC in the color correction of S243 is the latest γ table data and is proper.

On the other hand, when the received calibration number data 831 is different from the latest calibration number data 815 stored in the nonvolatile memory 10d (No in S262), in S266, image data is received from the personal computer PC and is erased. Then, in S267, the printer 1001 sends to the personal computer PC information informing that the r table data that has been used in the PC in the color correction of S243 is not the latest γ table data and is improper.

Returning to FIG. 21, when the personal computer PC receives the information that is issued by the printer 1001 in S265 or S267 of FIG. 22 (Yes in S207), the personal computer PC determines, based on the received information, whether or not the color correction processing that has been performed in S243 is proper, that is, whether or not the color correction processing is executed on the basis of the latest γ table data. When the personal computer PC receives in S207 the information that is issued by the printer 1001 in the process of S265, it is known that the color correction processing is proper, that is, the color correction processing has been executed by using the latest γ table data (Yes in S248), the processing is finished. On the other hand, when the personal computer PC receives in S207 the information that is issued by the printer 1001 in the process of S267, it is known that the color correction processing is improper, that is, the color correction processing has been executed by using the not-latest γ table data (No in S248), in S249, a comment to prompt the user to acquire the latest calibration data (latest γ table data and latest calibration number data) is displayed on a screen of the personal computer PC. When the user inputs his/her instruction to acquire the latest calibration data in the personal computer PC (Yes in S250), processing of acquiring the latest calibration data is executed in S251. That is, the personal computer PC requests the printer 1001 to send to the personal computer PC the latest calibration data (latest γ table data and latest calibration number data) that has been obtained at the latest-executed calibration processing of FIG. 14. Alternatively, the personal computer PC may instruct the printer 1001 to execute the calibration processing of FIG. 14 (yes in S110) so that the printer 1001 generates new calibration data (new γ table data and new calibration number data) and sends the new calibration data to the personal computers PC. After the latest calibration data is acquired in S251, the processing returns to S242. Accordingly, color correction is executed in S243 by using the newly-acquired latest γ table data.

On the other hand, when the user does not input any instruction to acquire the latest calibration data or no information is inputted for a predetermined period of time (No in S250), the processing is finished.

As described above, according to the second modification of the second embodiment, when the comparing unit 833 in the printer 1001 determines that the color correction processing is improper, the proper color correction information is outputted to the personal computer PC. Thus, the color correction processing can be realized on the side of the personal computer PC efficiently and properly.

### THIRD MODIFICATION OF THE SECOND EMBODIMENT

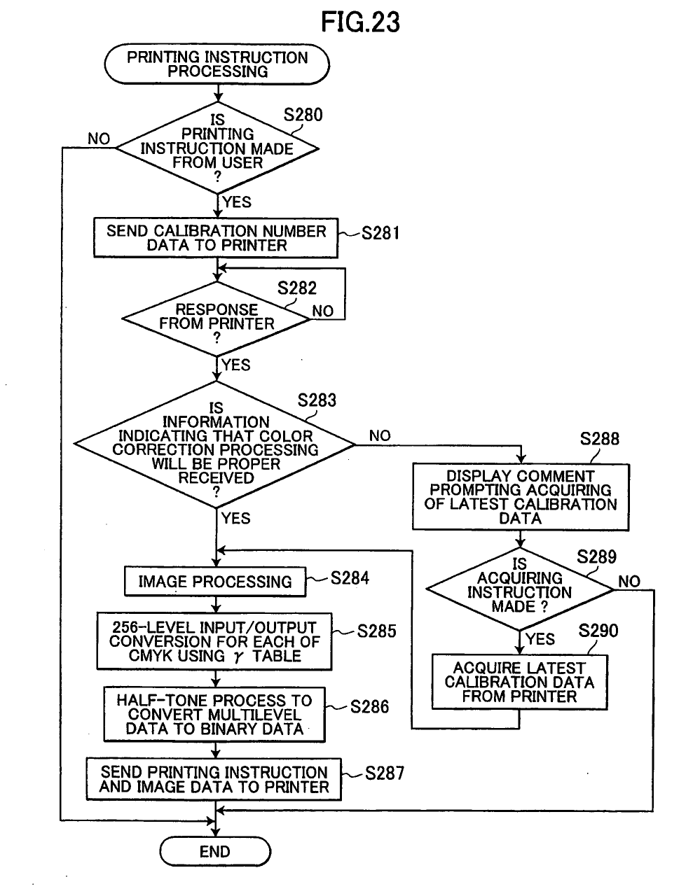

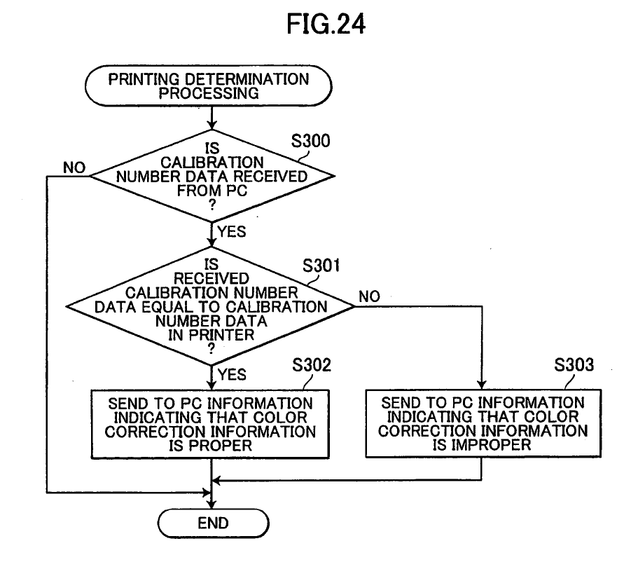

Next, a third modification of the second embodiment of the invention will be described with reference to FIG. 20, FIG. 23 and FIG. 24.

According to the present modification, the personal computer PC executes a printing instruction processing of FIG. 23 in place of the printing instruction processing of FIG. 16, and the printer 1001 executes the printing processing of FIG. 20 in place of the printing processing of FIG. 17 in the second embodiment. The printer 1001 further executes a printing determination processing of FIG. 24. It is noted that the printer 1001 executes the calibration executing processing of FIG. 14 in the same manner as in the second embodiment. The personal computer PC executes the calibration data receiving processing of FIG. 15 in the same manner as in the second embodiment.

More specifically, before the personal computer PC executes the color correction processing of S285 (FIG. 23), the printer 1001 determines whether or not the color correction processing will be proper and outputs the determination result to the personal computer PC. When the personal computer PC receives from the printer 1001 information indicating that the color correction processing will be improper, the personal computer PC acquires the latest color correction information, before executing the color correction processing.

The personal computer PC executes the printing instruction processing of FIG. 23 repeatedly regularly at relatively short time intervals. When the processing is started, first, in S280, the personal computer PC determines whether or not a printing instruction is issued from a user. In the absence of the printing instruction (No in S280), the processing is finished. In the existence of the printing instruction (Yes in S280), the calibration number data 831 stored in the personal computer PC is sent to the printer 1001 in S281. In S282, the personal computer PC waits for a response issued from the printer 1001.

FIG. 24 shows the printing determination processing executed by the printer 1001. The printing determination processing is also repeatedly executed regularly at relatively short time intervals.

When the processing is started, first, in S300, the printer 1001 determines whether or not calibration number data 831 is received from the personal computer PC. In the absence of the calibration number data (No in S300), the processing is finished. In the existence of the calibration number data (Yes in S300), in S301, the printer 1001 determines whether or not the received calibration number data 831 is equal to the latest calibration number data 815 that is presently being stored in the nonvolatile memory 10d.

When the received calibration number data 831 is equal to the latest calibration number data 815 (Yes in S301), in S302, the printer 1001 sends to the personal computer PC information indicating that the γ table data that the personal computer PC will use during the color correction processing of S285 (FIG. 23) is the latest γ table data and is proper.

On the other hand, when the received calibration number data 831 is different from the latest calibration number data 815 (No in S301), in S303, the printer 1001 sends to the personal computer PC information indicating that the γ table data that the personal computer PC will use during the color correction processing of S285 (FIG. 23) is not the latest γ table data and is improper.

Returning to FIG. 23, when the personal computer PC receives the information that is sent from the printer 1001 in S302 or S303 of FIG. 24 (Yes in S282), the personal computer PC determines whether or not the personal computer PC receives information indicating that the color correction processing will be proper.

When the personal computer PC receives the information that is sent from the printer 1001 in S302, it is known that the latest γ table data is stored in the personal computer PC (Yes in S283). Accordingly, processes of S284-S287 are executed in the same manner as in S205-S208 of FIG. 18 in the first modification of the second embodiment.

On the other hand, when the personal computer PC receives the information that is sent from the printer 1001 in S303, it is known that the non-latest γ table data is stored in the personal computer PC (No in S283). Accordingly, processes of S288-S290 are executed in the same manner as in S249-S251 of FIG. 21 in the second modification of the second embodiment. After the latest calibration data is acquired in S290 in the same manner as in S251, the processing returns to S284. Accordingly, color correction is executed in S285 by using the newly-acquired latest γ table data.

The printer 1001 acquires image data from the personal computer PC, and executes the printing processing as shown in FIG. 20 in the same manner as the first modification of the second embodiment.

As described above, in accordance with the third modification of the second embodiment, when the comparing unit 833 in the printer 1001 determines that the color correction processing will be improperly executed by using the non-latest calibration data, the personal computer PC acquires the latest calibration data without executing the color correction processing by the non-latest calibration data. Thus, the color correction processing can be performed on the side of the personal computer PC efficiently and properly.

While the invention has been described in detail with reference to the above aspects thereof, it would be apparent to those skilled in the art that various changes and modifications may be made therein without departing from the spirit of the invention.

For example, although the printers 1 and 1001 are the laser printers, the printers 1 and 1001 can be modified to other various kinds of printers such as ink jet printers, facsimile machines and to various image forming devices such as multiple-function processing machines having a printer function, a copy function and a facsimile function.

In the above description, γ table data is sent from the printer 1 or 1001 to the personal computers PC. However, other data, such as the measured density data 994, may be sent from the printer 1 or 1001 to the personal computers PC. In this case, based on the measured density data 994 sent from the printer 1 or 1001, the personal computer PC produces γ table data.

In the first embodiment, the γ table data that is attached to the e-mail and that is received by the personal computer PC is automatically stored in the personal computer PC in such a manner that the γ table data can be used by the printing instructing unit 730 in the personal computer PC. However, the user of the personal computer PC may manually install the received γ table data 995 in such a manner that the γ table data can be used by the printing instructing unit 730 in the personal computer PC.

When the printer 1 or 1001 is a so-called multi-function processing machine having a scanner unit as well, the scanner unit may be controlled to measure the printing density of each color in the measuring patches 992 printed on the sheet P. In this case, after the user of some personal computer PC controls the scanner unit of the printer 1 to read the measuring patches 992, the processing in S13 to S21 in FIG. 8 is executed to send the γ table data 995 to each member registered in the address book 812.

Furthermore, the measured density data 994, in place of the γ table data 995, may be attached to the mail and sent to each personal computer PC.

In the printing processing in accordance with the second embodiment (FIG. 17), processes of S155 and S158 may be omitted. That is, even when the calibration number is different from the latest calibration number (No in S153), after an error is displayed in S154, image data may be received in S156 and printed in S157.

In the second embodiment to the third modification of the second embodiment, it is determined whether or not the color correction processing is proper based on the latest calibration number data stored in the printer 1001 and the calibration number data that is associated with the image data to be printed. However, such calibration number data for identifying the color correction processing need not be used.

For example, the printer 1001 may store log data or history data indicating when the printer 1001 sends γ table data to the personal computers PC. Based on the log data, it is determined whether or not the γ table data that the personal computer PC uses is the latest γ table data. If the γ table data that the personal computer PC uses is different from the latest γ table data, it is known that the color correction processing that the personal computer PC executes is improper.

In the second embodiment to the third modification of the second embodiment, the printer 1001 generates the calibration number data 815 as identifying the γ table data. However, the personal computer PC may generate the calibration number data 815. For example, the printer 1001 may record data of time (date and time) when γ table data is updated. The personal computer PC records data of time (date and time) when the personal computer PC receives γ table data from the printer 1001. When instructing printing, the personal computer PC sends, to the printer 1001, image data and the data of time when the personal computer PC has received the γ table data from the printer 1001. The time data is associated with the image data. The printer 1001 compares the time when the personal computer PC has received the γ table data from the printer 1001 with the time when the γ table data has been updated at the latest, thereby judging whether or not the color correction processing that the personal computer PC attains is based on the latest γ table data.

In the second embodiment to the second modification of the second embodiment, after or before the personal computer PC executes the color correction processing, the personal computer PC may make an inquire to the printer 1001 and judge whether or not the color correction processing that the personal computer PC executes is based on the latest γ table data. When the color correction processing is not based on the latest γ table data, the personal computer sends an error signal, for example, to the printer 1001, without sending image data to the printer.

What is claimed is:

1. An image forming system comprising:
an image forming device, including
an image forming unit forming an image on the basis of image data sent from an outside;
a color correction information preparing unit preparing color correction information on the basis of an image forming state of the image forming unit; and
a color correction information sending unit sending the color correction information in association with the preparation of the color correction information by the color correction information preparing unit; and
a data processing device, including:
a color correction information receiving unit receiving the color correction information sent from the color correction information sending unit;
an image data correcting unit correcting image data on the basis of the received color correction information received by the color correction information receiving unit; and
an image data sending unit sending the corrected image data to the image forming device, the image forming unit in the image forming device forming an image on the basis of the image data.

2. An image forming system as claimed in claim 1, wherein the data processing device includes a color correction information storing unit storing the color correction information received by the color correction information receiving unit.

3. An image forming system as claimed in claim 2, wherein the color correction information storing unit stores the color correction information so as to be available by the image data correcting unit, and wherein on receipt of the color correction information by the color correction information receiving unit, the stored color correction information is automatically updated to the newly received color correction information.

4. An image forming system as claimed in claim 1, wherein the image forming device includes a destination storing unit storing data of destination of the color correction information and the color correction information sending unit sends the color correction information to a destination whose data is stored in the destination storing unit.

5. An image forming system as claimed in claim 1 further comprising a determining unit determining whether or not the color correction processing executed in the data processing device is proper.

6. An image forming system as claimed in claim 5 further comprising a disabling unit disabling image formation by the image forming unit on the basis of the image data when the determining unit determines that the color correction processing is improper.

7. An image forming system as claimed in claim 5, wherein the determining unit is configured to determine whether or not the color correction processing is proper prior to the color correction processing in the data processing device, and
further comprising a correction disabling unit disabling the color correction processing when the determining unit determines that the color correction processing is improper.

8. An image forming system as claimed in claim 5, wherein when the determining unit determines that the color correction processing is improper, the image forming device sends to the data processing device color correction information that enables proper color correction processing, and
the image data correcting unit in the data processing device executes the color correction processing on the basis of the color correction information that enables the proper color correction processing.

9. An image forming system, comprising:
a data processing device having a correcting unit executing color correction processing;
an image forming device having a receiving unit receiving image data that has been subjected to the color correction processing in the data processing device and an image forming unit forming an image on the basis of the image data received by the receiving unit; and
a determining unit determining whether or not the color correction processing executed in the data processing device is proper.

10. An image forming system as claimed in claim 9 further comprising a disabling unit disabling image formation by the image forming unit on the basis of the image data when the determining unit determines that the color correction processing is improper.

11. An image forming system as claimed in claim 9, wherein the determining unit is configured to determine whether or not the color correction processing is proper prior to the color correction processing in the data processing device, and
further comprising a correction disabling unit disabling the color correction processing when the determining unit determines that the color correction processing is improper.

12. An image forming system as claimed in claim 9, wherein when the determining unit determines that the color correction processing is improper, the image forming device sends to the data processing device color correction information that enables proper color correction processing, and
the image data correcting unit in the data processing device executes the color correction processing on the basis of the color correction information that enables the proper color correction processing.

13. An image forming device comprising:
an image forming unit forming an image on the basis of image data sent from the outside;
a color correction information preparing unit preparing, on the basis of an image forming state of the image forming unit, color correction information that is used for correcting color of image data: and
a color correction information sending unit sending the color correction information in association with the preparation of the color correction information by the color correction information preparing unit.

14. An image forming device as claimed in claim 13 further comprising a destination storing unit storing data of destination of the color correction information,
wherein the color correction information sending unit sends the color correction information to a destination whose data is stored in the destination storing unit.

15. An image forming device as claimed in claim 13, wherein the image forming unit receives image data that has been subjected to a color correcting processing in a data processing device and that has been sent from the data processing device, and forms an image on the basis of the image data,
further comprising a determining unit determining whether or not the color correction processing is proper.

16. An image forming device as claimed in claim 15 further comprising a disabling unit disabling image formation by the image forming unit on the basis of the image data when the determining unit determines that the color correction processing is improper.

17. An image forming device as claimed in claim 16, wherein the determining unit determines whether or not the color correction processing is proper on the basis of whether or not the color correction processing is executed based on the latest color correction information.

18. An image forming device as claimed in claim 15, wherein the image data is associated with identification information corresponding to color correction information that has been used during the color correction processing and the determining unit determines whether or not the color correction processing is proper on the basis of the identification information.

19. An image forming device as claimed in claim 18, wherein the identification information is information unique to a source device that has prepared the color correction information.

20. An image forming device as claimed in claim 15, further comprising:
an identification-information determining unit determining identification information corresponding to the color correction information generated by the color correction information preparing unit; and
an identification information storing unit storing latest identification information among the identification information that has been determined by the identification-information determining unit,
wherein the determining unit determines whether or not the color correction processing is proper by comparing the identification information associated with the image data with the latest identification information stored in the identification information storing unit.

21. An image forming device as claimed in claim 15, further comprising a measuring unit measuring density of a patch formed by the image forming unit, and
wherein the color correction information preparing unit generates the color correction information on the basis of the measured result by the measuring unit.

22. An image forming device as claimed in claim 15, further comprising an informing unit informing the fact that the determining unit determines that the color correction processing is improper.

23. An image forming device as claimed in claim 15, further comprising an instructing unit allowing the image forming unit to form an image according to the image data that has been subjected to the color correction processing that is determined to be improper by the determining unit.

24. An image forming device as claimed in claim 15, wherein prior to the color correction processing in the data processing device, the determining unit determines whether or not the color correction processing is proper.

25. An image forming device as claimed in claim 15, wherein the determining unit outputs information for executing the color correction processing to the data processing device when determining that the color correction processing is proper and outputs information for disabling the color correction processing to the data processing device when determining that the color correction processing is improper.

26. An image forming device as claimed in claim 15, wherein when the determining unit determines that the color correction processing is improper, the color correction information sending unit sends to the data processing device color correction information that is used for executing proper color correction processing.

27. An image forming device comprising:
an image data receiving unit receiving image data that has been subjected to a color correction processing in a data processing device;
an image forming unit forming an image on the basis of the image data received by the image data receiving unit; and
a determining unit determining whether or not the color correction processing executed in the data processing device is proper.

28. An image forming device as claimed in claim 27 further comprising a disabling unit disabling image formation by the image forming unit on the basis of the image data when the determining unit determines that the color correction processing is improper.

29. An image forming device as claimed in claim 28 further comprising:
a color correction information preparing unit generating color correction information used for the color correction processing; and
a color correction information sending unit outputting the color correction information to the data processing device.

30. An image forming device as claimed in claim 27, wherein the determining unit determines whether or not the color correction processing is proper on the basis of whether or not the color correction processing is executed based on the latest color correction information.

31. An image forming device as claimed in claim 27, wherein the image data is associated with identification information corresponding to the color correction information and the determining unit determines whether or not the color correction processing is proper on the basis of the identification information.

32. An image forming device as claimed in claim 31, wherein the identification information is information unique to a source device that has prepared the color correction information.

33. An image forming device as claimed in claim 27, further comprising:
a color correction information preparing unit generating color correction information used for the color correction processing;
a color correction information sending unit outputting the color correction information to the data processing device;
an identification-information determining unit determining identification information corresponding to the color correction information generated by the color correction information preparing unit; and
an identification information storing unit storing latest identification information among the identification information that has been determined by the identification-information determining unit,
wherein the determining unit determines whether or not the color correction processing is proper by comparing the identification information associated with the image data with the latest identification information stored in the identification information storing unit.

34. An image forming device as claimed in claim 27, further comprising a measuring unit measuring density of a patch formed by the image forming unit, and
the color correction information preparing unit generates the color correction information on the basis of the measured result by the measuring unit.

35. An image forming device as claimed in claim 27, further comprising an informing unit informing the fact that the determining unit determines that the color correction processing is improper.

36. An image forming device as claimed in claim 27, further comprising an instructing unit allowing the image forming unit to form an image according to the image data that has been subjected to the color correction processing that is determined to be improper by the determining unit.

37. An image forming device as claimed in claim 27, wherein prior to the color correction processing in the data processing device, the determining unit determines whether or not the color correction processing is proper.

38. An image forming device as claimed in claim 27, wherein the determining unit outputs information for executing the color correction processing to the data processing device when determining that the color correction processing is proper and outputs information for disabling the color correction processing to the data processing device when determining that the color correction processing is improper.

39. An image forming device as claimed in claim 27, wherein when the determining unit determines that the color correction processing is improper, the color correction information sending unit sends to the data processing device the color correction information that is used for executing proper color correction processing.

40. A data processing device comprising:
a color correction information receiving unit receiving color correction information;
a color correction information storing unit storing the color correction information received by the color correction information receiving unit;
an image data correcting unit correcting image data on the basis of the color correction information stored in the color correction information storing unit; and
an image data sending unit sending the corrected image data to an image forming device.

41. A data processing device as claimed in claim 40, wherein the color correction information storing unit stores the color correction information to be available by the image data correcting unit, and wherein on receipt of the color correction information by the color correction information receiving unit, the stored color correction information is automatically updated to the newly received color correction information.
